(19) United States
(12) Patent Application Publication
(10) Pub. No.: US 2006/0011907 A1
(43) Pub. Date: Jan. 19, 2006

(54) Compounds containing 3,4-methylenedioxythiophene units

(75) Inventors: Lutz Brassat, Leverkusen (DE); Stephan Kirchmeyer, Leverkusen (DE); Knud Reuter, Krefeld (DE)

Correspondence Address: Kurt G. Briscoe;Norris, McLaughlin & Marcus P.A., 18th Floor, 875 Third Avenue, New York, NY, 10022, US

(73) Assignee: H. C. Starck GmbH, Goslar (DE)

(21) Appl. No.: 11/120,850

(22) Filed: May 3, 2005

(30) Foreign Application Priority Data
May 15, 2004 (DE) 102004024271. 2

(51) Int. Cl. H01L 29/08; H01L 35/24; C08G 75/32

(52) U.S. Cl. 257/40; 528/377

(57) ABSTRACT

The invention relates to compounds containing optionally substituted 3,4-methylenedioxythiophene units (thieno[3,4-d]-1,3-dioxole units), 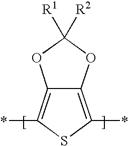 the production thereof and their use as organic semi-conductors.

The invention relates to compounds containing optionally substituted 3,4-methylenedioxythiophene units (thieno[3,4-d]-1,3-dioxole units), the production thereof and their use as organic semiconductors.

The field of molecular electronics has developed rapidly over the last 15 years with the discovery of organic conductive and semi-conductive compounds. During this period, a great many compounds exhibiting semi-conductive or electro-optical properties have been found. It is generally understood that molecular electronics will not replace conventional, silicon-based semi-conductor devices. Instead, it is assumed that molecular electronic components will open up new areas of application in which their suitability for coating large areas, structural flexibility, processability at low temperatures and low costs are required. Semi-conductive organic compounds are currently being developed for areas of application such as organic field-effect transistors (OFETs), organic light-emitting diodes (OLEDs), sensors and photovoltaic elements. By simple structuring and integration of OFETs into integrated organic semi-conductor circuits, inexpensive solutions are possible for smart cards or price labels that could not previously be achieved using silicon technology because of the price and the lack of flexibility of the silicon components. OFETs could also be used as circuit elements in large-area, flexible matrix displays. An overview of organic semi-conductors, integrated semi-conductor circuits and their applications is described e.g. in Electronics 2002, volume 15, p. 38.

Known semi-conductive organic compounds are e.g. polyfluorenes and fluorene copolymers, such as e.g. poly(9,9-dioctylfluorene-co-bithiophene), with which charge carrier mobilities, also referred to below as mobilities for short, of up to 0.02 cm²/Vs have been achieved (Science, 2000, volume 290, p. 2123). Mobilities of up to 0.1 cm²/Vs have even been achieved with regioregular poly(3-hexylthiophen-2,5-diyl) (Science, 1998, volume 280, p. 1741). Other representatives of semi-conductive organic compounds are e.g. oligothiophenes, particularly those with terminal alkyl substituents, and pentacene. Typical mobilities, for e.g. α,α′-dihexylquater-, quinque- and sexithiophene are 0.05-0.1 cm² Vs. The compounds described above have only limited suitability for use in (opto)electronic components, however. Thus, for example, some of these compounds have phase transitions which rule out their use above a temperature typical of the compound in question, or their mobilities are inadequate for some applications.

There have been several attempts to produce oligomers from alkylenedioxythiophene units, particularly from 3,4-ethylenedioxythiophene units, and to use them as organic semi-conductors. It is a disadvantage, however, that these oligoalkylenedioxythiophenes, especially the corresponding 3,4-ethylenedioxythiophene compounds, are very sensitive to oxidation. As a result, their use as an organic semi-conductor is only possible to a limited extent, since any doping of the organic semi-conductor would lead to poor current modulation. Only in the very recent past have syntheses of oligo(3,4-ethylenedioxythiophenes) exhibiting reduced sensitivity to oxidation been described by Roncali et al., Journal of Organic Chemistry, 2003, 68, 5357-5360. No results are yet known for this compound with respect to its suitability for use as organic semi-conductors in transistors or other (opto)electronic components, however.

The need therefore still exists for compounds that can be used as organic semi-conductors.

The object was therefore to produce novel, semi-conductive, organic compounds which exhibit low sensitivity to oxidation and are well suited to use as organic semi-conductors in opto(electronic) components.

Surprisingly, it has now been found that neutral compounds, i.e. those present in the non-oxidised form, containing 3,4-methylenedioxythiophene units, also referred to below in simplified form but with the same meaning as methylenedioxythiophene units, have a high degree of oxidative stability and can be used as semi-conductors.

The present invention provides neutral compounds containing identical or different repeating units of general formula (I) and optionally containing identical or different repeating units of general formula (II) 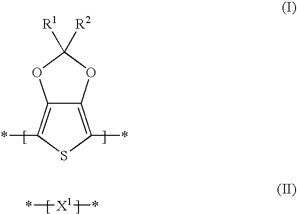
wherein
R¹ and R² independently of one another denote H, a linear or branched, optionally substituted C₁-C₂₀ alkyl group, optionally interrupted by 1 to 5 oxygen and/or sulfur atoms, a partially fluorinated or a perfluorinated, linear or branched C₁-C₂₀ alkyl group, a linear or branched C₁-C₂₀ oxyalkyl group, an optionally substituted C₆-C₂₄ aryl group, an optionally substituted C₆-C₂₄ alkylaryl group, an optionally substituted C₆-C₂₄ oxyaryl group or an optionally substituted C₂-C₂₄ heteroaryl group, or together denote an optionally substituted C₁-C₂₀ alkylene group, optionally interrupted by 1 to 5 oxygen and/or sulfur atoms, a C₁-C₂₀ dioxyalkylene group, a C₆-C₃₀ dialkylenearylene group or a C₆-C₂₄ dioxyarylene group,
X¹ denotes an optionally substituted vinylidene, arylidene or a hetarylidene unit,
   the number of repeating units of general formula (I) is n and the number of repeating units of general formula (II) is m, wherein
n denotes an integer from 1 to 1000, preferably from 1 to 200 and
m denotes an integer from 0 to 1000, preferably from 0 to 20,
   with the proviso that m+n is at least 2, preferably an integer from 2 to 2000, particularly preferably an integer from 3 to 220,
and the compound has terminal groups R³ and R⁴, wherein
R³ and R⁴ independently of one another denote H, a linear or branched C₁-C₂₀ alkyl group, a partially fluorinated or a perfluorinated, linear or branched C₁-C₂₀ alkyl group, a linear or branched C₁-C₂₀ oxyalkyl group, an optionally substituted C₆-C₂₄ aryl group, an optionally substituted C₁-C₂₀ alkylaryl group, an optionally substituted C₁-C₂₀ oxyaryl group or an optionally substituted C₁-C₂₀ heteroaryl group.

In formulae (I) and (II) the asterisk (*) denotes a binding position for adjacent groups or terminal groups R³ or R⁴.

The compounds according to the invention are polymers. Within the framework of the invention, polymers comprise all compounds in which n+m is an integer greater than 1. Furthermore, the term polymers is understood to mean all those compounds that are either polydisperse, i.e. have a molecular weight distribution, or monodisperse, i.e. have a uniform molecular weight. The compounds according to the invention are preferably monodisperse within the meaning of the above definition. The compounds according to the invention can be homopolymers of identical repeating units of general formula (I) or copolymers of several different repeating units of general formula (I) or several identical or different repeating units of general formulae (I) and (II). The repeating units can be arranged in the copolymer randomly, alternately or in blocks. Within the framework of the invention, the term repeating units means all units of general formulae (I) and (II), regardless of whether they are contained in the polymer once or more than once.

If not otherwise indicated, optionally substituted means a substitution with a substituent selected from the group of alkyl, in particular C₁-C₆ alkyl, cycloalkyl, in particular C₆-C₁₄ cycloalkyl, aryl, in particular C₆-C₁₂ aryl, aralkyl, in particular C₇-C₁₄ aralkyl, halogen, in particular F, Cl, Br and J, oxyalkyl, oxyaryl, ether, thioether disulfide, sulfoxide, sulfone, sulfonate, amino, aldehyde, keto, carboxylic acid ester, carboxylic acid, carbonate, carboxylate, cyano, alkylsilane and alkoxysilane groups as well as carboxamide groups.

In general formula (I), R¹ and R² preferably denote, independently of one another, H, a linear or branched, optionally substituted C₁-C₂₀ alkyl group optionally interrupted by 1 to 5 oxygen and/or sulfur atoms, such as e.g. methyl, ethyl, n-propyl, iso-propyl, n-butyl, sec-butyl, iso-butyl, tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl, n-octadecyl or n-eicosyl, a partially fluorinated or a perfluorinated, linear or branched C₁-C₂₀ alkyl group, such as e.g. trifluoromethyl, pentafluoroethyl, heptafluoropropyl, nonafluorobutyl, perfluoropentyl, perfluorohexyl, perfluoroheptyl, perfluorooctyl, perfluorononyl, perfluorodecyl, perfluoroundecyl, perfluorododecyl, perfluorotridecyl, perfluorotetradecyl, perfluorohexadecyl, perfluorooctadecyl, perfluoroeicosyl, a linear or branched C₁-C₂₀ oxyalkyl group, such as e.g. methoxy, ethoxy, n- or iso-propoxy, n-, iso-, sec- or tert-butoxy, n-pentyloxy, 1-methylbutyloxy, 2-methylbutyloxy, 3-methylbutyloxy, 1-ethylpropyloxy, 1,1-dimethylpropyloxy, 1,2-dimethylpropyloxy, 2,2-dimethylpropyloxy, n-hexyloxy, n-heptyloxy, n-octyloxy, 2-ethylhexyloxy, n-nonyloxy, n-decyloxy, n-undecyloxy, n-dodecyloxy, n-tridecyloxy, n-tetradecyloxy, n-hexadecyloxy, n-octadecyloxy, n-nonadecyloxy or n-eicosyloxy, an optionally substituted C₆-C₂₄ aryl group, such as e.g. phenyl, naphthyl, anthryl, methylphenyl, ethylphenyl, pentylphenyl, butylphenyl, dimethylphenyl, biphenylyl, an optionally substituted C₆-C₂₄ alkylaryl group, such as e.g. benzyl, an optionally substituted C₆-C₂₄ oxyaryl group, such as e.g. phenoxy, or an optionally substituted C₂-C₂₄ heteroaryl group, such as e.g. 2-thienyl, 3-thienyl, 2-furanyl, 3-furanyl, 2-pyrrolyl, 3-pyrrolyl, pyrazolyl, thiazolyl, 2-pyridyl, 3-pyridyl, 4-pyridyl, quinolinyl, oxazolyl and thiazolyl, or together denote an optionally substituted C₁-C₂₀ alkylene group, optionally interrupted by 1 to 5 oxygen and/or sulfur atoms, such as e.g. 1,2-ethylene, 1,3-propylidene, 1,4-butylidene, 1,5-pentylidene, a C₁-C₂₀ dioxyalkylene group, a C₆-C₃₀ dialkylenearylene group, such as e.g. 1,2-xylidene, or a C₆-C₂₄ dioxyarylene group. In general formula (I), R³ and R⁴ preferably denote, independently of one another, H, an optionally substituted, linear or branched C₁-C₂₀ alkyl group, such as e.g. methyl, ethyl, n-propyl, iso-propyl, n-butyl, sec-butyl, iso-butyl, tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl, n-octadecyl or n-eicosyl, a partially fluorinated or a perfluorinated, linear or branched C₁-C₂₀ alkyl group, such as e.g. trifluoromethyl, pentafluoroethyl, heptafluoropropyl, perfluorobutyl, perfluoropentyl, perfluorohexyl, perfluoroheptyl, perfluorooctyl, perfluorononyl, perfluorodecyl, perfluoroundecyl, perfluorododecyl, perfluorotridecyl, perfluorotetradecyl, perfluorohexadecyl, perfluorooctadecyl and perfluoroeicosyl, an optionally substituted, linear or branched C₁-C₂₀ oxyalkyl group, an optionally substituted C₆-C₂₄ aryl group, such as e.g. phenyl, biphenylyl or pentafluorophenyl, an optionally substituted C₁-C₂₀ alkylaryl group, such as e.g. benzyl, methylphenyl, ethylphenyl, dimethylphenyl, an optionally substituted C₁-C₂₀ oxyaryl group, such as e.g. phenyloxy and biphenyloxy, or an optionally substituted C₁-C₂₀ heteroaryl group, such as e.g. 2-thienyl, 3-thienyl, 2-furanyl, 3-furanyl, 2-pyrrolyl, 3-pyrrolyl, pyrazolyl, thiazolyl, 2-pyridyl, 3-pyridyl, 4-pyridyl, quinolinyl, oxazolyl and thiazolyl.

In general formula (II), X¹ preferably denotes an optionally substituted vinylidene, arylidene or a hetarylidene unit, such as e.g. 1,4-phenylene, 2,5-thienylene, 1,4′-biphenylene, 2,5-thienylene-vinylene, 2,5′-bithienylene, 2,5″-terthienylene, 2,5′″-quaterthienylene. Numerous organic groups are suitable as optional other substituents of R¹ to R⁴ or X¹, e.g. alkyl, partially fluorinated or perfluorinated alkyl, cycloalkyl, aryl, halogen, ether, thioether, disulfide, sulfoxide, sulfone, sulfonate, amino, aldehyde, keto, carboxylic acid ester, carboxylic acid, carbonate, carboxylate, cyano, alkylsilane and alkoxysilane groups as well as carboxylamide groups.

The following are mentioned as examples of the compounds according to the invention:

Bis(methylenedioxythiophene), ter(methylenedioxythiophene), quater(methylenedioxythiophene), quinque(methylenedioxythiophene), sexi(methylenedioxythiophene), septi(methylenedioxythiophene), octi(methylenedioxythiophene), poly(methylenedioxythiophene), bis(1′,1′-ethylidenedioxythiophene), ter(1′,1′-ethylidenedioxythiophene), quater(1′,1′-ethylidenedioxythiophene), quinque(1′,1′-ethylidenedioxythiophene), sexi(1′,1′-ethylidenedioxythiophene), septi(1′,1′-ethylidenedioxythiophene), octi(1′,1′-ethylidenedioxythiophene), poly(1′,1′-ethylidenedioxythiophene), bis(1′,1′-propylidenedioxythiophene), ter(1′,1′-propylidenedioxythiophene), quater(1′,1′-propylidenedioxythiophene), quinque(1′,1′-propylidenedioxythiophene), sexi(1′,1′-propylidenedioxythiophene), septi(1′,1′-propylidenedioxythiophene), octi(1′,1′-propylidenedioxythiophene), poly(1′,1′-propylidenedioxythiophene), bis(2′,2′-propylidenedioxythiophene), ter(2′,2′-propylidenedioxythiophene), quater(2′,2′-propylidenedioxythiophene), sexi(2′,2′-propylidenedioxythiophene), poly(2′,2′-propylidenedioxythiophene), bis(1′,1′-butylidenedioxythiophene), ter(1′,1′-butylidenedioxythiophene), quater(1′,1′-butylidenedioxythiophene), quinque(1′,1′-butylidenedioxythiophene), sexi(1′,1′-butylidenedioxythiophene), poly(1′,1′-butylidenedioxythiophene), bis(2′,2′-butylidenedioxythiophene), quater(2′,2′-butylidenedioxythiophene), quinque(2′,2′-butylidenedioxythiophene), sexi(2′,2′-butylidenedioxythiophene), poly(2′,2′-butylidenedioxythiophene), bis(1′,1′-pentylidenedioxythiophene), sexi(1′,1′-pentylidenedioxythiophene), poly(1′,1′-pentylidenedioxythiophene), bis(2′,2′-pentylidenedioxythiophene), quater(2′,2′-pentylidenedioxythiophene), sexi(2′,2′-pentylidenedioxythiophene), poly(2′,2′-pentylidenedioxythiophene), bis(3′,3′-pentylidenedioxythiophene), quater(3′,3′-pentylidenedioxythiophene), sexi(3′,3′-pentylidenedioxythiophene), poly(3′,3′-pentylidenedioxythiophene), bis(1′,1′-hexylidenedioxythiophene), quater(1′,1′-hexylidenedioxythiophene), sexi(1′,1′-hexylidenedioxythiophene), poly(1′,1′-hexylidenedioxythiophene), bis(2′,2′-hexylidenedioxythiophene), quater(2′,2′-hexylidenedioxythiophene), sexi(2′,2′-hexylidenedioxythiophene), poly(2′,2′-hexylidenedioxythiophene), bis(3′,3′-hexylidenedioxythiophene), quater(3′,3′-hexylidenedioxythiophene), sexi(3′,3′-hexylidenedioxythiophene), poly(3′,3′-hexylidenedioxythiophene), bis(1′,1′-cyclopentylidenedioxythiophene), ter(1′,1′-cyclopentylidenedioxythiophene), quater(1′,1′-cyclopentylidenedioxythiophene), quinque(1′,1′-cyclopentylidenedioxythiophene), sexi(1′,1′-cyclopentylidenedioxythiophene), poly(1′,1′-cyclopentylidenedioxythiophene), bis(1′,1′-cyclohexylidenedioxythiophene), quater(1′,1′-cyclohexylidenedioxythiophene), sexi(1′,1′-cyclohexylidenedioxythiophene), poly(1′,1′-cyclohexylidenedioxythiophene), bis(1′,1′-cyclobutylidenedioxythiophene), bis(1′,1′-cyclopropylidenedioxythiophene), bis(1′,1′-benzylidenedioxythiophene), poly(1′,1′-benzylidenedioxythiophene), bis(2′-phenyl-1′,1′-ethylidenedioxythiophene), sexi(2′-phenyl-1′,1′-ethylidenedioxythiophene), poly(2′-phenyl- 1′,1′-ethylidenedioxythiophene). The list is intended to explain the invention by examples and should not be considered final.

The above compounds with 1′,1′-ethylidenedioxythiophene groups are compounds with one or more building block(s) of the following structure:

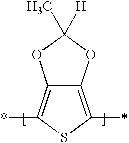

The present invention preferably provides those compounds according to the invention containing the repeating units of general formula (I) in a proportion of at least 10 mole %.

The present invention also preferably provides those compounds according to the invention in which R¹ or R² denotes H.

The present invention also preferably provides those compounds according to the invention in which R¹ and R² denote H.

The following are listed as examples of these compounds according to the invention:

2-Ethylbis(methylenedioxythiophene), 2-ethylter(methylenedioxythiophene), 2-ethylquater(methylenedioxythiophene), 2-ethylquinque(methylenedioxythiophene), 2-ethylsexi(methylenedioxythiophene), 2-ethylsepti(methylenedioxythiophene), 2-ethylocti(methylenedioxythiophene), 2-propylbis(methylenedioxythiophene), 2-propylter(methylenedioxythiophene), 2-propylquater(methylenedioxythiophene), 2-propylquinque(methylenedioxythiophene), 2-propylsexi(methylenedioxythiophene), 2-propylsepti(methylenedioxythiophene), 2-propylocti(methylenedioxythiophene), 2-butylbis(methylenedioxythiophene), 2-butylter(methylenedioxythiophene), 2-butylquater(methylenedioxythiophene), 2-butylquinque(methylenedioxythiophene), 2-butylsexi(methylenedioxythiophene), 2-butylsepti(methylenedioxythiophene), 2-butylocti(methylenedioxythiophene), 2-pentylbis(methylenedioxythiophene), 2-pentylter(methylenedioxythiophene), 2-pentylquater(methylenedioxythiophene), 2-pentylquinque(methylenedioxythiophene), 2-pentylsexi(methylenedioxythiophene), 2-pentylsepti(methylenedioxythiophene), 2-pentylocti(methylenedioxythiophene), 2-hexylbis(methylenedioxythiophene), 2-hexylter(methylenedioxythiophene), 2-hexylquater(methylenedioxythiophene), 2-hexylquinque(methylenedioxythiophene), 2-hexylsexi(methylenedioxythiophene), 2-hexylsepti(methylenedioxythiophene), 2-hexylocti(methylenedioxythiophene), 2-phenylbis(methylenedioxythiophene), 2-phenylter(methylenedioxythiophene), 2-phenylquater(methylenedioxythiophene), 2-phenylquinque(methylenedioxythiophene), 2-phenylsexi(methylenedioxythiophene), 2-phenylsepti(methylenedioxythiophene), 2-phenylocti(methylenedioxythiophene), 2,5′-diethylbis(methylenedioxythiophene), 2,5′-dipropylbis(methylenedioxythiophene), 2,5′-dibutylbis(methylenedioxythiophene), 2,5′-dipentylbis(methylenedioxythiophene), 2,5′-dihexylbis(methylenedioxythiophene), 2,5′-dioctylbis(methylenedioxythiophene), 2,5′-diphenylbis(methylenedioxythiophene), 2,5″-dimethylter(methylenedioxythiophene), 2,5″-diethylter(methylenedioxythiophene), 2,5″-dipropylter(methylenedioxythiophene), 2,5″-dibutylter(methylenedioxythiophene), 2,5″-dihexylter(methylenedioxythiophene), 2,5″-dioctylter(methylenedioxythiophene), 2,5″-didecylter(methylenedioxythiophene), 2,5″-didodecylter(methylenedioxythiophene), 2,5′″-dimethylquater(methylenedioxythiophene), 2,5′″-diethylquater(methylenedioxythiophene), 2,5′″-dihexylquater(methylenedioxythiophene), 2,5′″-didecylquater(methylenedioxythiophene), 2,5″″-diethylquinque(methylenedioxythiophene), 2,5″″-dihexylquinque(methylenedioxythiophene), 2,5″″-didecylquinque(methylenedioxythiophene), 2,5′″″-d imethylsexi(methylenedioxythiophene), 2,5′″″-diethylsexi(methylenedioxythiophene), 2,5′″″-dihexylsexi(methylenedioxythiophene), 2,5′″″-diphenylsexi(methylenedioxythiophene), 2,5′-thienylbis(methylenedioxythiophene), 2,5′-bis(2-ethylthien-5-yl)bis(methylenedioxythiophene), 2,5′-bis(2-hexylthien-5-yl)bis(methylenedioxythiophene), 2-quaterthienyl methylenedioxythiophene, 2-terthienyl-5-thienyl methylenedioxythiophene, 2,5-di(bithienyl) methylenedioxythiophene, 2-terthienyl methylenedioxythiophene, 2-bithienyl-5-thienyl methylenedioxythiophene, 2-bisthienyl methylenedioxythiophene, 2-thienyl methylenedioxythiophene, 2-quaterphenyl methylenedioxythiophene, 2-terphenyl-5-phenyl methylenedioxythiophene, 2,5-bis(biphenyl) methylenedioxythiophene, 2-terphenyl methylenedioxythiophene, 2-biphenylyl-5-phenyl methylenedioxythiophene, 2-biphenylyl methylenedioxythiophene, 2-phenyl methylenedioxythiophene. The list is intended to explain the invention by examples and should not be considered final.

The present invention also preferably provides those compounds according to the invention in which R³ and R⁴ denote H.

The present invention also preferably provides those compounds according to the invention in which m equals 0.

These are the compounds according to the invention of general formula (III), 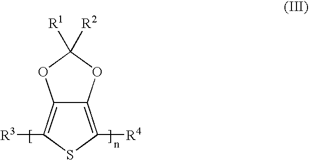
wherein R¹, R², R³, R⁴ and n have the meaning given above for general formulae (I) and (II). Preferred ranges and combinations of these preferred ranges are similarly applicable.

In preferred embodiments, these are the compounds of the general formula (III-a) 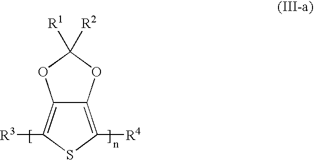
wherein R¹ or R² denotes H and R³, R⁴ and n have the meaning given above for general formulae (I) and (II). Preferred ranges and combinations of these preferred ranges are similarly applicable. In especially preferred embodiments, these are the compounds in which R¹ denotes H and R² denotes methyl.

The following are mentioned as examples of these compounds according to the invention of general formula (III-a):

Bis(1′,1′-ethylidenedioxythiophene), ter(1′,1′-ethylidenedioxythiophene), quater(1′,1′-ethylidenedioxythiophene), quinque(1′,1′-ethylidenedioxythiophene), sexi(1′,1′-ethylidenedioxythiophene), septi(1′,1′-ethylidenedioxythiophene), octi(1′,1′-ethylidenedioxythiophene), 2-ethylbis(1′,1′-ethylidenedioxythiophene), 2-ethylter(1′,1′-ethylidenedioxythiophene), 2-ethylquater(1′,1′-ethylidenedioxythiophene), 2-ethylquinque(1′,1′-ethylidenedioxythiophene), 2-ethylsexi( 1′,1′-ethylidenedioxythiophene), 2-ethylsepti(1′,1′-ethylidenedioxythiophene), 2-ethylocti(1′,1′-ethylidenedioxythiophene), 2-propylbis(1′,1′-ethylidenedioxythiophene), 2-propylter(1′,1′-ethylidenedioxythiophene), 2-propylquater(1′,1′-ethylidenedioxythiophene), 2-propylquinque(1′,1′-ethylidenedioxythiophene), 2-propylsexi(1′,1′-ethylidenedioxythiophene), 2-propylsepti(1′,1′-ethylidenedioxythiophene), 2-propylocti(1′,1′-ethylidenedioxythiophene), 2-butylbis(1′,1′-ethylidenedioxythiophene), 2-butylter(1′,1′-ethylidenedioxythiophene), 2-butylquater(1′,1′-ethylidenedioxythiophene), 2-butylquinque(1′,1′-ethylidenedioxythiophene), 2-butylsexi( 1′,1′-ethylidenedioxythiophene), 2-butylsepti(1′,1′-ethylidenedioxythiophene), 2-butylocti(1′,1′-ethylidenedioxythiophene), 2-pentylbis(1′,1′-ethylidenedioxythiophene), 2-pentylter(1′,1′-ethylidenedioxythiophene), 2-pentylquater(1′,1′-ethylidenedioxythiophene), 2-pentylquinque(1′,1′-ethylidenedioxythiophene), 2-pentylsexi(1′,1′-ethylidenedioxythiophene), 2-pentylsepti(1′,1′-ethylidenedioxythiophene), 2-pentylocti(1′,1′-ethylidenedioxythiophene), 2-hexylbis(1′,1′-ethylidenedioxythiophene), 2-hexylter(1′,1′-ethylidenedioxythiophene), 2-hexylquater(1′,1′-ethylidenedioxythiophene), 2-hexylquinque(1′,1′-ethylidenedioxythiophene), 2-hexylsexi(1′,1′-ethylidenedioxythiophene), 2-hexylsepti(1′,1′-ethylidenedioxythiophene), 2-hexylocti(1′,1′-ethylidenedioxythiophene), 2-phenylbis(1′,1′-ethylidenedioxythiophene), 2-phenylter(1′,1′-ethylidenedioxythiophene), 2-phenylquater(1′,1′-ethylidenedioxythiophene), 2-phenylquinque(1′,1′-ethylidenedioxythiophene), 2-phenylsexi(1′,1′-ethylidenedioxythiophene), 2-phenylsepti(1′,1′-ethylidenedioxythiophene), 2-phenylocti(1′,1′-ethylidenedioxythiophene), 2,5′-diethylbis(1′,1′-ethylidenedioxythiophene), 2,5′-dipropylbis(1′,1′-ethylidenedioxythiophene), 2,5′-dibutylbis(1′,1′-ethylidenedioxythiophene), 2,5′-dipentylbis(1′,1′-ethylidenedioxythiophene), 2,5′-dihexylbis(1′,1′-ethylidenedioxythiophene), 2,5′-dioctylbis(1′,1′-ethylidenedioxythiophene), 2,5″-diphenylbis(1′,1′-ethylidenedioxythiophene), 2,5″-dimethylter(1′,1′-ethylidenedioxythiophene), 2,5″-diethylter(1′,1′-ethylidenedioxythiophene), 2,5″-dipropylter(1′,1′-ethylidenedioxythiophene), 2,5″-dibutylter(1′,1′-ethylidenedioxythiophene), 2,5″-dihexylter(1′,1′-ethylidenedioxythiophene), 2,5″-dioctylter(1′,1′-ethylidenedioxythiophene), 2,5″-didecylter(1′,1′-ethylidenedioxythiophene), 2,5″-didodecylter(1′,1′-ethylidenedioxythiophene), 2,5′″dimethylquater(1′,1′-ethylidenedioxythiophene), 2,5′″-diethylquater(1′,1′-ethylidenedioxythiophene), 2,5′″-dihexylquater(1′,1′-ethylidenedioxythiophene), 2,5′″-didecylquater(1′,1′-ethylidenedioxythiophene), 2,5″″-diethylquinque(1′,1′-ethylidenedioxythiophene), 2,5″″-dihexylquinque(1′,1′-ethylidenedioxythiophene), 2,5″″didecylquinque(1′,1′-ethylidenedioxythiophene), 2,5′″″-dimethylsexi(1′,1′-ethylidenedioxythiophene), 2,5′″″-diethylsexi(1′,1′-ethylidenedioxythiophene), 2,5′″″-dihexylsexi(1′,1′-ethylidenedioxythiophene), 2,5′″″-diphenylsexi(1′,1′-ethylidenedioxythiophene), 2-pentafluoroethylbis(1′,1′-ethylidenedioxythiophene), 2-pentafluoroethylter(1′,1′-ethylidenedioxythiophene), 2-pentafluoroethylquater(1′,1′-ethylidenedioxythiophene), 2-pentafluoroethylquinque(1′,1′-ethylidenedioxythiophene), 2-pentafluoroethylsexi(1′,1′-ethylidenedioxythiophene), 2-pentafluoroethylsepti(1′,1′-ethylidenedioxythiophene), 2-pentafluoroethylocti(1′,1′-ethylidenedioxythiophene), 2-heptafluoropropylbis(1′,1′-ethylidenedioxythiophene), 2-heptafluoropropylter(1′,1′-ethylidenedioxythiophene), 2-heptafluoropropylquater(1′,1′-ethylidenedioxythiophene), 2-heptafluoropropylquinque(1′,1′-ethylidenedioxythiophene), 2-heptafluoropropylsexi(1′,1′-ethylidenedioxythiophene), 2-heptafluoropropylsepti(1′,1′-ethylidenedioxythiophene), 2-heptafluoropropylocti(1′,1′-ethylidenedioxythiophene), 2-perfluorobutylbis(1′,1′-ethylidenedioxythiophene), 2-perfluorobutylter(1′,1′-ethylidenedioxythiophene), 2-perfluorobutylquater(1′,1′-ethylidenedioxythiophene), 2-perfluorobutylquinque(1′,1′-ethylidenedioxythiophene), 2-perfluorobutylsexi(1′,1′- ethylidenedioxythiophene), 2-perfluorobutylsepti(1′,1′-ethylidenedioxythiophene), 2-perfluorobutylocti(1′,1′-ethylidenedioxythiophene), 2-perfluorophentylbis(1′,1′-ethylidenedioxythiophene), 2-perfluoropentylter(1′,1′-ethylidenedioxythiophene), 2-perfluoropentylquater(1′,1′-ethylidenedioxythiophene), 2-perfluoropentylquinque(1′,1′-ethylidenedioxythiophene), 2-perfluoropentylsexi(1′,1′-ethylidenedioxythiophene), 2-perfluoropentylsepti(1′,1′-ethylidenedioxythiophene), 2-perfluoropentylocti(1′,1′-ethylidenedioxythiophene), 2-perfluorohexylbis(1′,1′-ethylidenedioxythiophene), 2-perfluorohexylter( 1′,1′-ethylidenedioxythiophene), 2-perfluorohexylquater(1′,1′-ethylidenedioxythiophene), 2-perfluorohexylquinque(1′,1′-ethylidenedioxythiophene), 2-perfluorohexylsexi(1′,1′-ethylidenedioxythiophene), 2-perfluorohexylsepti(1′,1′-ethylidenedioxythiophene), 2-perfluorohexylocti(1′,1′-ethylidenedioxythiophene), 2-phenylbis(1′,1′-ethylidenedioxythiophene), 2-phenylter(1′,1′-ethylidenedioxythiophene), 2-phenylquater(1′,1′-ethylidenedioxythiophene), 2-phenylquinque(1′,1′-ethylidenedioxythiophene), 2-phenylsexi(1′,1′-ethylidenedioxythiophene), 2-phenylsepti(1′,1′-ethylidenedioxythiophene), 2-phenylocti(1′,1′-ethylidenedioxythiophene), 2,5′-bis(pentafluoroethyl)bis(1′,1′-ethylidenedioxythiophene), 2,5′-bis(heptafluoropropyl)bis( 1′,1′-ethylidenedioxythiophene), 2,5′-diperfluorobutylbis(1′,1′-ethylidenedioxythiophene), 2,5′-diperfluoropentylbis(1′,1′-ethylidenedioxythiophene), 2,5′-diperfluorohexylbis(1′,1′-ethylidenedioxythiophene), 2,5′-dioctylbis(1′,1′-ethylidenedioxythiophene), 2,5′-bis(heptafluorophenyl)bis(1′,1′-ethylidenedioxythiophene), 2,5″-bis(trifluoromethyl)ter(1′,1′-ethylidenedioxythiophene), 2,5″-bis(heptafluoroethyl)ter(1′,1′-ethylidenedioxythiophene), 2,5″-bis(pentafluoropropyl)ter(1′,1′-ethylidenedioxythiophene), 2,5″-bis(perfluorobutyl)ter(1′,1′-ethylidenedioxythiophene), 2,5″-bis(perfluorohexyl)ter(1′,1′-ethylidenedioxythiophene), 2,5″-bis(perfluorooctyl)ter(1′,1′-ethylidenedioxythiophene), 2,5″-bis(perfluorodecyl)ter(1′,1′-ethylidenedioxythiophene), 2,5″-bis(perfluorododecyl)ter(1′,1′-ethylidenedioxythiophene), 2,5′″-bis(trifluoromethyl)quater(ethylenedioxythiophene), 2,5′″-bis(pentafluoroethyl)quater(1′,1′-ethylidenedioxythiophene), 2,5′″-bis(perfluorohexyl)quater(1′,1′-ethylidenedioxythiophene), 2,5′″-bis(perfluorodecyl)quater(1′,1′-ethylidenedioxythiophene), 2,5″″-bis(pentafluoroethyl)quinque(1′,1′-ethylidenedioxythiophene), 2,5″″-bis(perfluorohexyl)quinque(1′,1′-ethylidenedioxythiophene), 2,5″″-bis(perfluorodecyl)quinque(1′,1′-ethylidenedioxythiophene), 2,5′″″bis(trifluoromethyl)sexi(1′,1′-ethylidenedioxythiophene), 2,5′″″-bis(pentafluoroethyl)sexi(1′,1′-ethylidenedioxythiophene), 2,5′″″-bis(perfluorohexyl)sexi(1′,1′-ethylidenedioxythiophene), 2,5′″″-bis(pentafluorophenyl)sexi(1′,1′-ethylidenedioxythiophene). The list is intended to explain the invention by examples and should not be considered final.

In other preferred embodiments, the compounds according to the invention are those of general formula (III-b), 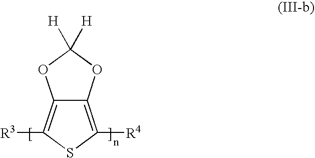
wherein R¹ and R² denote H, and R³, R⁴ and n have the meaning given above for general formulae (I) and (II). Preferred ranges and combinations of these preferred ranges are similarly applicable.

In addition to those already contained in previous lists, the following are mentioned as examples of these compounds of formula (III-b) according to the invention:

2-Pentafluoroethylbis(methylenedioxythiophene), 2-pentafluoroethylter(methylenedioxythiophene), 2-pentafluoroethylquater(methylenedioxythiophene), 2-pentafluoroethylquinque(methylenedioxythiophene), 2-pentafluoroethylsexi(methylenedioxythiophene), 2-pentafluoroethylsepti(methylenedioxythiophene), 2-pentafluoroethylocti(methylenedioxythiophene), 2-heptafluoropropylbis(methylenedioxythiophene), 2-heptafluoropropylter(methylenedioxythiophene), 2-heptafluoropropylquater(methylenedioxythiophene), 2-heptafluoropropylquinque(methylenedioxythiophene), 2-heptafluoropropylsexi(methylenedioxythiophene), 2-heptafluoropropylsepti(methylenedioxythiophene), 2-heptafluoropropylocti(methylenedioxythiophene), 2-perfluorobutylbis(methylenedioxythiophene), 2-perfluorobutylter(methylenedioxythiophene), 2-perfluorobutylquater(methylenedioxythiophene), 2-perfluorobutylquinque(methylenedioxythiophene), 2-perfluorobutylsexi(methylenedioxythiophene), 2-perfluorobutylsepti(methylenedioxythiophene), 2-perfluorobutylocti(methylenedioxythiophene), 2-perfluoropentylbis(methylenedioxythiophene), 2-perfluoropentylter(methylenedioxythiophene), 2-perfluoropentylquater(methylenedioxythiophene), 2-perfluoropentylquinque(methylenedioxythiophene), 2-perfluoropentylsexi(methylenedioxythiophene), 2-perfluoropentylsepti(methylenedioxythiophene), 2-perfluoropentylocti(methylenedioxythiophene), 2-perfluorohexylbis(methylenedioxythiophene), 2-perfluorohexylter(methylenedioxythiophene), 2-perfluorohexylquater(methylenedioxythiophene), 2-perfluorohexylquinque(methylenedioxythiophene), 2-perfluorohexylsexi(methylenedioxythiophene), 2-perfluorohexylsepti(methylenedioxythiophene), 2-perfluorohexylocti(methylenedioxythiophene), 2-phenylbis(methylenedioxythiophene), 2-phenylter(methylenedioxythiophene), 2-phenylquater(methylenedioxythiophene), 2-phenylquinque(methylenedioxythiophene), 2-phenylsexi(methylenedioxythiophene), 2-phenylsepti(methylenedioxythiophene), 2-phenylocti(methylenedioxythiophene), 2,5′-bis(pentafluoroethyl)bis(methylenedioxythiophene), 2,5′-bis(heptafluoropropyl)bis(methylenedioxythiophene), 2,5′-bis(perfluorobutyl)bis(methylenedioxythiophene), 2,5′-bis(perfluoropentyl)bis(methylenedioxythiophene), 2,5′-bis(perfluorohexyl)bis(methylenedioxythiophene), 2,5′-dioctylbis(methylenedioxythiophene), 2,5′-bis(pentafluorophenyl)bis(methylenedioxythiophene), 2,5″-bis(trifluoromethyl)ter(methylenedioxythiophene), 2,5″-bis(heptafluoroethyl)ter(methylenedioxythiophene), 2,5″-bis(pentafluoropropyl)ter(methylenedioxythiophene), 2,5″-bis(perfluorobutyl)ter(methylenedioxythiophene), 2,5″-bis(perfluorohexyl)ter(methylenedioxythiophene), 2,5″-bis(perfluorooctyl)ter(methylenedioxythiophene), 2,5″-(perfluorodecyl)ter(methylenedioxythiophene), 2,5″-bis(perfluorodecyl)ter(methylenedioxythiophene), 2,5′″-bis(trifluoromethyl)quater(methylenedioxythiophene), 2,5′″-bis(pentafluoroethyl)quater(methylenedioxythiophene), 2,5′″-bis(perfluorohexyl)quater(methylenedioxythiophene), 2,5′″-bis(perfluorodecyl)quater(methylenedioxythiophene), 2,5″″-bis(pentafluoroethyl)quinque(methylenedioxythiophene), 2,5″″-bis(perfluorohexyl)quinque(methylenedioxythiophene), 2,5″″-bis(perfluorodecyl)quinque(methylenedioxythiophene), 2,5′″″-bis(trifluoromethyl)sexi(methylenedioxythiophene), 2,5′″″-bis(pentafluoroethyl)sexi(methylenedioxythiophene), 2,5′″″-bis(perfluorohexyl)seximethylenedioxythiophene), 2,5′″″-bis(pentafluorophenyl)sexi(methylenedioxythiophene). The list is intended to explain the invention by examples and should not be considered final.

In other preferred embodiments, the compounds according to the invention are those of general formula (III-c), 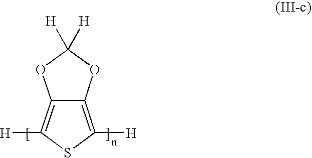
wherein R¹, R², R³ and R⁴ denote H and n has the meaning given above for general formula (I). Preferred ranges are similarly applicable.

The following are mentioned as examples of these compounds of general formula (III-c):

Bis(methylenedioxythiophene), ter(methylenedioxythiophene), quater(methylenedioxythiophene), quinque(methylenedioxythiophene), sexi(methylenedioxythiophene), septi(methylenedioxythiophene), octi(methylenedioxythiophene), novi(methylenedioxythiophene), deci(methylenedioxythiophene), undeci(methylenedioxythiophene), dodeci(methylenedioxythiophene) and poly(methylenedioxythiophene). The list is intended to explain the invention by examples and should not be considered final.

In principle, it is possible to produce the compounds according to the invention by means of various processes known in principle to the person skilled in the art based on at least one organometallic reaction.

The invention also therefore provides a process for the production of a compound according to the invention, wherein the compound according to the invention is produced by at least one organometallic reaction.

This is preferably a process in which the compound according to the invention is produced by a Kumada coupling, Suzuki coupling or Stille coupling.

In a preferred embodiment, the compounds according to the invention are produced by a variant of Suzuki coupling, often also referred to as Suzuki condensation. The Suzuki condensation or Suzuki coupling, i.e. the reaction of aryl halides and arylboronic acid compounds with a Pd compound as catalyst in the presence of a base, is described e.g. in Suzuki et al., Chem. Rev. 1995, 95, 2457-2483. In a preferred embodiment, the process according to the invention is carried out by a variant of this Suzuki coupling according to the invention, wherein organyl halides or organyl boronates are reacted optionally in the presence of at least one base and/or at least one catalyst containing a metal of subgroup VIII of the periodic table, referred to below for short as a metal of subgroup VIII.

The preferred embodiment of the process according to the invention (Suzuki coupling) is carried out at a temperature of +20° C. to +200° C., preferably +40° C. to +150° C., particularly preferably +80° C. to +130° C., in an organic solvent or solvent mixture.

In principle, all suitable compounds containing a metal of subgroup VIII, preferably Pd, Ni or Pt, particularly preferably Pd, can be used as catalysts containing a metal of subgroup VIII. The catalyst or catalysts are preferably used in quantities of 0.05 wt. % to 10 wt. %, particularly preferably 0.5 wt. % to 5 wt. %, based on the total weight of the compounds to be coupled.

Particularly suitable catalysts are complexes of metals of subgroup VIII, especially complexes of palladium(0), which are stable in air, Pd complexes that can readily be reduced with organometallic reagents (e.g. lithium alkyl compounds or organomagnesium compounds) or phosphines to form palladium(0) complexes, or palladium(2) complexes, optionally with the addition of PPh₃ or other phosphines. For example, PdCl₂(PPh₃)₂, PdBr₂(PPh₃)₂ or Pd(OAc)₂ or mixtures of these compounds can be used with the addition of PPh₃. Pd(PPh₃)₄ is preferably used, with or without the addition of phosphines, and in a preferred embodiment without the addition of phosphines, which is available in an inexpensive form. As phosphines, PPh₃, PEtPh₂, PMePh₂, PEt₂Ph or PEt₃ are preferably used, particularly preferably PPh₃.

However, it is also possible to use palladium compounds without the addition of phosphines as catalysts, such as e.g. Pd(OAc)₂.

As the base, for example hydroxides, such as e.g. NaOH, KOH, LiOH, Ba(OH)₂, Ca(OH)₂, alkoxides, such as e.g. NaOEt, KOEt, LiOEt, NaOMe, KOMe, LiOMe, alkali metal salts of carboxylic acids, such as e.g. sodium, potassium or lithium carbonate, hydrogen carbonate, acetate, citrate, acetylacetonate, glycinate, or other carbonates, such as e.g. Cs₂CO₃ or Tl₂CO₃, phosphates, such as e.g. sodium phosphate, potassium phosphate or lithium phosphate, or mixtures of these, can be used. Sodium carbonate is preferably used. The bases can be used as solutions in water or suspensions in organic solvents, such as toluene, dioxane or DMF. Solutions in water are preferred, as the products obtained can be readily separated from the reaction mixture in this case, owing to their low solubility in water.

It is also possible to use other salts, such as e.g. LiCl or LiBr, as auxiliary substances.

In principle, all solvents or solvent mixtures that do not react with the boronates are suitable as the organic solvents. These are generally compounds which do not contain any halogen atoms or any hydrogen atoms that are reactive towards boronates. Suitable solvents are e.g. alkanes, such as pentane, hexane and heptane, aromatics, such as benzene, toluene and xylenes, compounds containing ether groups, such as dioxane, dimethoxyethane and tetrahydrofuran, and polar solvents, such as dimethyl formamide or dimethyl sulfoxide. Aromatics are preferably used as solvents in the process according to the invention. Toluene is especially preferred. It is also possible to use mixtures of two of more of these solvents as the solvents.

The organyl halides used in this process can be produced by known methods or are commercially available. The production of the boronates can take place e.g. by the reaction of aryl halides and bis(organyl) diborane by metal-catalysed coupling (WO-A 01/29051 Al, Tetrahedron Lett. 2002, p. 5649), by coupling of oligothiophene halides with e.g. pinacol borane (J. Org. Chem. 1997, vol. 62, p. 6458; J. Organomet. Chem. 2001, vol. 640, p. 197; Chem. Commun. 2002, p. 1566) or by reaction of organometallic compounds, e.g. organomagnesium compounds (e.g. Grignard compounds) or organolithium compounds, with boronates. These methods are known to the person skilled in the art.

In another preferred embodiment, the compounds according to the invention are produced by means of a Kumada coupling. The Kumada coupling, i.e. the reaction of an aryl halide and an aryl Grignard compound in the presence of a Pd or an Ni catalyst, is described e.g. in Kumada et al., J. Am. Chem. Soc. 1972, 94, 4373-4376. In a preferred embodiment, the process according to the invention is carried out by a variant of this Kumada coupling according to the invention, in which aryl or heteroaryl halides and Grignard compounds of aryl or heteroaryl halides are reacted in the presence of a catalyst containing a metal of subgroup VIII of the periodic table, referred to below for short as a metal of subgroup VIII. The preferred embodiment of the process according to the invention (Kumada coupling) is carried out at a temperature of 0° C. to 200° C., preferably +20° C. to +150° C., particularly preferably +40° C. to +130° C, in an organic solvent or a solvent mixture.

In principle, all suitable compounds containing a metal of subgroup VIII, preferably Pd or Ni, particularly preferably Pd, can be used as catalysts containing a metal of subgroup VIII. The catalyst or catalysts are preferably used in quantities of 0.05 wt. % to 10 wt. %, particularly preferably 0.5 wt. % to 5 wt. %, based on the total weight of the compounds to be coupled.

Particularly suitable catalysts are complexes of metals of subgroup VIII, especially complexes of palladium(0), which are stable in air, Pd complexes that can readily be reduced with organometallic reagents (e.g. lithium alkyl compounds or organomagnesium compounds) or phosphines to form palladium(0) complexes, or palladium(2) complexes, optionally with the addition of PPh₃ or other phosphines. For example, PdCl₂(PPh₃)₂, PdBr₂(PPh₃)₂ or Pd(OAc)₂ or mixtures of these compounds can be used with the addition of diphenylphosphinoethane (dppe) or diphenylphosphinopropane (dppp) or 1,1′-bis(diphenylphosphino)ferrocene (dppf). PdCl₂ (dppe), PdCl₂ (dppp) and PdCl₂ (dppf) are preferably used as catalysts.

In principle, all solvents or solvent mixtures that do not react with the Grignard reagents are suitable as the organic solvents. These are generally compounds which do not contain any halogen atoms or any hydrogen atoms that are reactive towards Grignard compounds. Suitable solvents are e.g. aromatics, such as benzene, toluene and xylenes, compounds containing ether groups, such as dioxane, dimethoxyethane, diethyl ether, dibutyl ether and tetrahydrofuran. Ethereal solvents are preferably used in the process according to the invention. Tetrahydrofuran is especially preferred. It is also possible to use mixtures of two or more of these solvents as the solvents.

In another preferred embodiment, the compounds according to the invention are produced by means of a Stille coupling. The Stille coupling, i.e. the reaction of an aryl halide and an aryl or alkenyl stannyl compound in the presence of a Pd catalyst is described e.g. in Stille et al., Angew. Chem. 1986, 98, 504. In a preferred embodiment, the process according to the invention is carried out by a variant of this Stille coupling according to the invention, in which aryl or heteroaryl halides and aryl and alkenyl stannyl compounds are reacted in the presence of a catalyst containing a metal of subgroup VIII of the periodic table, referred to below for short as a metal of subgroup VIII. The preferred embodiment of the process according to the invention (Stille coupling) is carried out at a temperature of 0° C. to 200° C., preferably +20° C. to +150° C., particularly preferably +40° C. to +130° C., in an organic solvent or a solvent mixture.

In principle, all suitable compounds containing a metal of subgroup VIII, particularly preferably Pd, can be used as catalysts containing a metal of subgroup VIII. The catalyst or catalysts are preferably used in quantities of 0.05 wt. % to 10 wt. %, particularly preferably 0.5 wt. % to 5 wt. %, based on the total weight of the compounds to be coupled.

Particularly suitable catalysts are complexes of metals of subgroup VIII, especially complexes of palladium(0), which are stable in air, Pd complexes that can readily be reduced with organometallic reagents (e.g. lithium alkyl compounds or organomagnesium compounds) or phosphines to form palladium(0) complexes, or palladium(2) complexes, optionally with the addition of PPh₃ or other phosphines. For example, PdCl₂(PPh₃)₂, PdBr₂(PPh₃)₂ or Pd(OAc)₂ or mixtures of these compounds can be used with the addition of PPh₃. Pd(PPh₃)₄ is preferably used, with or without the addition of phosphines, and in a preferred embodiment without the addition of phosphines, which is available in an inexpensive form. As phosphines, PPh₃, PEtPh₂, PMePh₂, PEt₂Ph or PEt₃ are preferably used, particularly preferably PPh₃.

However, it is also possible to use palladium compounds without the addition of phosphines as catalysts, such as e.g. Pd(OAc)₂.

In principle, all solvents or solvent mixtures that do not react with the stannyl compounds are suitable as the organic solvents. These are generally compounds which do not contain any halogen atoms or any hydrogen atoms that are reactive towards stannyl compounds. Suitable solvents are e.g. aromatics, such as benzene, toluene and xylenes, compounds containing ether groups, such as dioxane, dimethoxyethane, diethyl ether, dibutyl ether and tetrahydrofuran, or polar solvents, such as dimethyl formamide, N-methylpyrrolidone or acetonitrile. It is also possible to use mixtures of two or more of these solvents as the solvents.

The reaction mixtures are each worked up by methods that are known per se, e.g. by dilution, precipitation, filtration, extraction, washing, recrystallisation from suitable solvents, chromatography and/or sublimation. For example, a work-up can take place in that the reaction mixture is poured, after completion of the reaction, into a mixture of acid (iced) water, e.g. made from 1-molar hydrochloric acid, and toluene, the organic phase is separated off, washed with water, the product obtained as a solid is filtered off, washed with toluene and then dried in vacuo. The compounds according to the invention can be obtained in high quality and purity even without any subsequent additional purification processes. However, it is possible to purify these products further by known methods, e.g. by recrystallisation, chromatography or sublimation.

The compounds according to the invention are electrically neutral and semi-conductive and exhibit low sensitivity to oxidation. In addition, they can be readily applied from solution. Consequently, they are highly suitable for use as organic semi-conductors in (opto)electronic components.

This is surprising in so far as the monomeric parent compound 3,4-methylenedioxythiophene or thieno[3,4-d]-1,3-dioxole, is known to the person skilled in the art from a series of publications and he had to assume that compounds with methylenedioxythiophene units behave similarly to other compounds containing 3,4-alkylenedioxythiophene units. Thus, it was to be expected that compounds containing methylenedioxythiophene units would have a stable charged or oxidised state and the neutral state would be rather unstable. Thus, for example, polymers of methylenedioxythiophene are described only in the oxidised, i.e. cationic form by Ahonen et al., Synthetic Metals (1997), 84(1-3), 215-216, and can thus be used not as semi-conductors but as organic conductors (cf. EP-A 339 340). Non-oxidised, i.e. neutral compounds with 3,4-methylenedioxythiophene units have not been described in the literature up to the present.

The present invention therefore also provides the use of the compounds according to the invention as organic semi-conductors in electronic components, in active and light-emitting electronic components, such as field effect transistors, organic light-emitting diodes, photovoltaic cells, lasers or sensors.

For this purpose, the compounds according to the invention are applied in the form of layers on to suitable substrates, e.g. on to silicon wafers, polymer films or panes of glass provided with electrical or electronic structures. In principle, all application methods known to the person skilled in the art are suitable for the application. For example, the compounds of general formula (I) can be applied from the gas phase or from solution, in which case the solvent is then evaporated. Application from solution can take place by the known methods, e.g. by spraying, dipping, printing and knife-coating, spin-coating and by ink-jet printing. The compounds according to the invention can also be applied from the gas phase, e.g. by vapour deposition. In this way, layers with the smallest defects and highest charge mobilities can be obtained.

The present invention therefore also provides an electronic component containing at least one compound according to the invention.

The following examples serve to explain and illustrate the invention by examples, but do not represent any limitation.

### EXAMPLES

### Example 1

### Synthesis of bis(methylenedioxythiophene) (III-c-1) (bis-MDT)

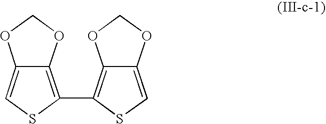 3.96 g of 3,4-methylenedioxythiophene are dissolved in 100 ml dehydrated (abs.) tetrahydrofuran (THF) under an N₂ atmosphere and cooled to 0° C. 20 ml of 1.6 M n-butyllithium solution in n-hexane are added dropwise to the solution cooled to 0° C. The mixture is stirred for 30 min at 0° C. 4.41 g of CuCl₂ are then added all at once and the mixture is then stirred for 12 h at 23° C. After pouring into ice/water, 1.9 g (=48% of theoretical value) of bis(3,4-methylenedioxythiophene) (III-c-1) are sucked off.

Mp. 225-231° C. Elemental analysis: Measured: C: 46.7% H: 2.25% S: 24.6% Calculated: C: 47.0% H: 2.37% S: 25.6% (for C₁₀H₆O₄S₂) ¹H-NMR spectrum (CDCl₃; ppm δ against TMS): 6.00 (2H), 6.28 (4H)

### Example 2

### Synthesis of 2-hexylbis(methylenedioxythiophene) (III-b-1)

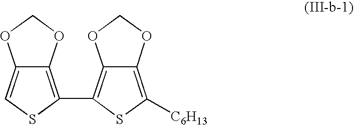

3.52 ml of 2.5 M butyllithium solution in hexane are added to 20 ml of anhydrous THF at −20° C. The mixture is stirred for 1 h and then 2.03 g of bis-MDT (III-c-1), produced in accordance with Example 1, in 50 ml THF are added. The mixture is stirred for a further hour at −20° C. and then 1.65 g of hexyl bromide are added at −20° C. The reaction mixture is thawed and hydrolysed with water. The aqueous phase is extracted three times with 50 ml methylene chloride each time and the solvent is completely removed from the combined organic phases. 0.7 g of 2-hexylbis(methylenedioxythiophene) are obtained as a light-grey solid after chromatography on silica gel.

### Example 3

### Synthesis of 2,5′″-dihexylquater(methylenedioxythiophene) (III-b-2)

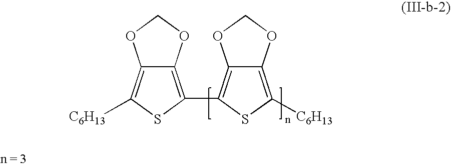 1 ml of 1.6 M n-butyllithium solution in n-hexane is initially added to 20 ml THF at −70° C. 0.157 ml of diisopropylamine are then added dropwise and the mixture is stirred for 1 h. 0.5 g of 2-hexylbis(methylenedioxythiophene)—produced in accordance with Example 2—are then added dropwise at −78° C. The mixture is thawed to −20° C. and stirred for 1 h. It is then cooled again to −78° C. and approx. 0.16 g of anhydrous copper(II) chloride are added. The mixture is stirred for 1 h at −70° C. and then thawed to 23° C. It is then hydrolysed with water, the aqueous phase is extracted three times with 50 ml methylene chloride each time and the solvent is completely removed from the combined organic phases. 0.24 g of 2,5′″-dihexylquater(methylenedioxythiophene) (III-b-2) are obtained as a yellowish brown powder.

1. Neutral compound comprising identical or different repeating units of formula (I) and optionally comprising identical or different repeating units of formula (II): 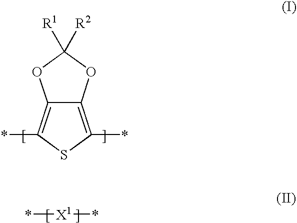
wherein
R¹ and R² independently of one another denote H, a linear or branched, optionally substituted C₁-C₂₀ alkyl group, optionally interrupted by 1 to 5 oxygen and/or sulfur atoms, a partially fluorinated or a perfluorinated, linear or branched C₁-C₂₀ alkyl group, a linear or branched C₁-C₂₀ oxyalkyl group, an optionally substituted C₆-C₂₄ aryl group, an optionally substituted C₆-C₂₄ alkylaryl group, an optionally substituted C₆-C₂₄ oxyaryl group or an optionally substituted C₂-C₂₄ heteroaryl group or together denote an optionally substituted C₁-C₂₀ alkylene group, optionally interrupted by 1 to 5 oxygen and/or sulfur atoms, a C₁-C₂₀ dioxyalkylene group, a C₆-C₃₀ dialkylenearylene group or a C₆-C₂₄ dioxyarylene group,
X¹ denotes an optionally substituted vinylidene, arylidene or a hetarylidene unit,
the number of repeating units of formula (I) is n and the number of repeating units of formula (II) is m, wherein
n denotes an integer from 1 to 1000 and
m denotes an integer from 0 to 1000,
with the proviso that m+n is at least 2,
and the compound has terminal groups R³ and R⁴, wherein
R³ and R⁴ independently of one another denote H, a linear or branched C₁-C₂₀ alkyl group, a partially fluorinated or a perfluorinated, linear or branched C₁-C₂₀ alkyl group, a linear or branched C₁-C₂₀ oxyalkyl group, an optionally substituted C₆-C₂₄ aryl group, an optionally substituted C₁-C₂₀ alkylaryl group, an optionally substituted C₁-C₂₀ oxyaryl group or an optionally substituted C₁-C₂₀ heteroaryl group.

2. Compound according to claim 1, which comprises repeating units of formula (I) in a proportion of at least 10 mole %.

3. Compound according to claim 1, wherein R¹ and/or R² denotes H.

4. Compound according to claim 1, wherein R³ and R⁴ denote H.

5. Compound according to claim 1, wherein m equals 0 and n denotes an integer from 2 to 1000.

6. Process for the production of a compound according to claim 1, comprising subjecting one or more precursors of the the compound to at least one organometallic reaction.

7. Process according to claim 6, wherein the compound is produced by a Kumada coupling, Suzuki coupling or Stille coupling.

8. An electronic component comprising at least one compound according to claim 1.

9. Electronic component according to claim 8, which is selected from the group of field-effect transistors, light-emitting components, photovoltaic cells, lasers and sensors.

10. Electronic device which comprises at least one compound according to claim 1.
